(19) United States
(12) Patent Application Publication
(10) Pub. No.: US 2026/0314469 A1
(43) Pub. Date: Oct. 8, 2026

(54) Semiconductor Device and Method of Making a Dual-Side Molded System-in-Package with Tall components and Patterned E-Bars

(71) Applicant: JCET STATS ChipPAC Korea Limited, Incheon (KR)

(72) Inventors: SeungHyun Lee, Incheon (KR); SangHoon Lee, Incheon (KR); SunYoung Kim, Incheon (KR); SangJun Park, Incheon (KR); Gyeongmin Kim, Incheon (KR); HeeSoo Lee, Incheon (KR)

(73) Assignee: JCET STATS ChipPAC Korea Limited, Incheon (KR)

(21) Appl. No.: 19/171,680

(22) Filed: Apr. 7, 2025

(51) Int. Cl. H01L 21/56; H01L 21/48; H01L 23/00; H01L 23/31; H01L 23/498; H01L 23/552; H01L 25/18

(52) U.S. Cl. CPC H10W 74/016; H10W 42/20; H10W 70/099; H10W 74/114; H10W 74/121; H10W 90/701; H10W 72/0198; H10W 74/00; H10W 90/00; H10W 90/724

(57) ABSTRACT

A semiconductor device has a substrate. An opening is formed through the substrate. An insulating film is laminated onto a first surface of the substrate. A first electrical component is disposed on the insulating film in the opening. A second electrical component is disposed on a second surface of the substrate opposite the first surface. A first encapsulant is deposited over the first electrical component and second electrical component. The insulating film is removed. A third electrical component is disposed over the first surface of the substrate. An e-bar is disposed on the first surface of the substrate. A second encapsulant is deposited over the third electrical component and e-bar.

### FIELD OF THE INVENTION

The present invention relates in general to semiconductor devices and, more particularly, to a semiconductor device and method of making a dual-side molded system-in-package with tall components and patterned e-bars.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. At the same time, more and more complex semiconductor devices are demanded by device manufacturers. Portable devices require larger batteries to maintain real-time responsiveness. The large batteries in turn require big inductors and capacitors, typically placed in an electronic device as discrete parts along with a semiconductor package used to control battery charging and discharging.

In recent years, the large inductors and capacitors are being moved into system-in-package modules rather than being used as discrete parts, which helps reduce the overall footprint required in the electronic device. However, placing large capacitors and inductors in system-in-package modules increases the height of the package and creates additional problems. Therefore, a need exists for a semiconductor device and method of making a dual-side molded system-in-package with tall components and patterned e-bars.

### BRIEF DESCRIPTION OF THE DRAWINGS

FIGS. 1a-1c illustrate a semiconductor wafer with a plurality of semiconductor die separated by a saw street;

FIGS. 2a-2k illustrate forming a dual-side molded system-in-package with tall components;

FIGS. 3a-3d illustrate an alternative process flow;

FIGS. 4a-4h illustrate using patterned e-bars; and

FIGS. 5a and 5b illustrate an electronic device with the dual-side molded system-in-package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The terms “semiconductor die” and “die” as used herein are synonymous and refer to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

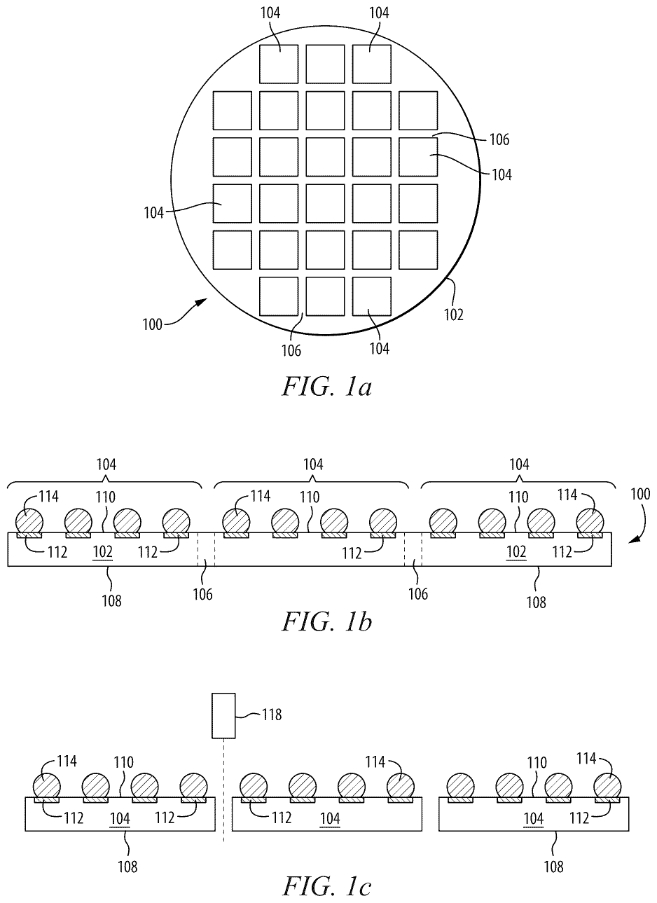

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Lead (Pb), Bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

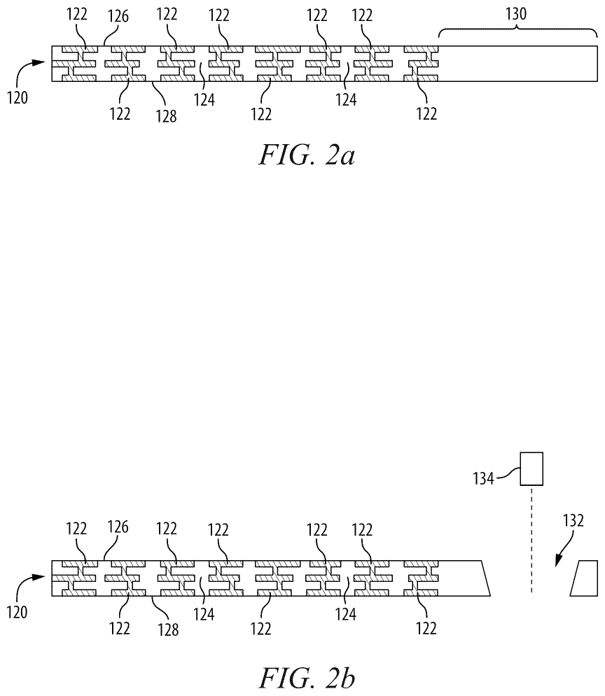

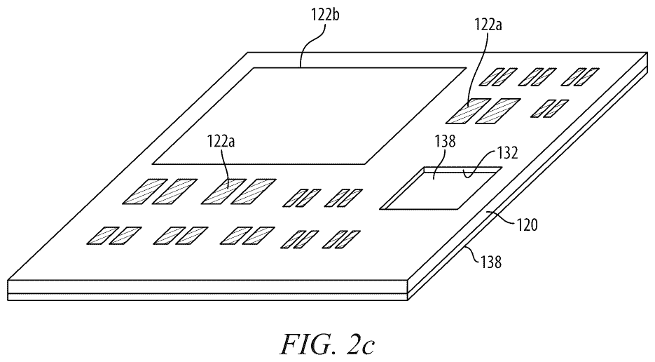

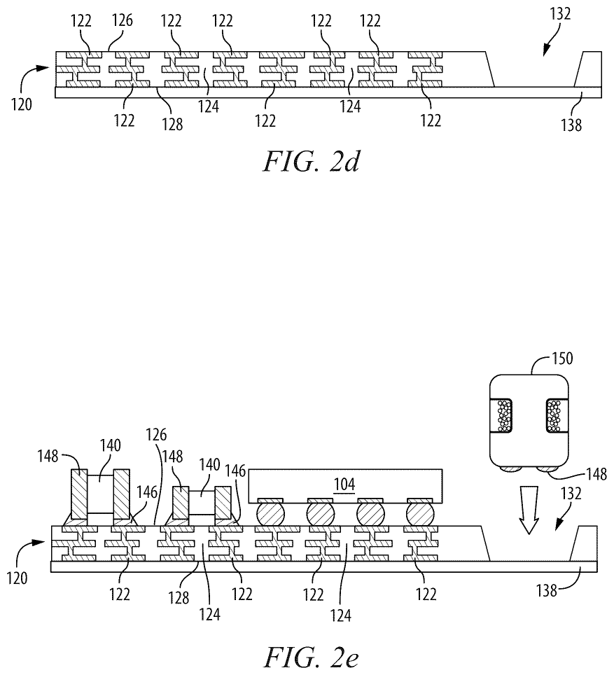

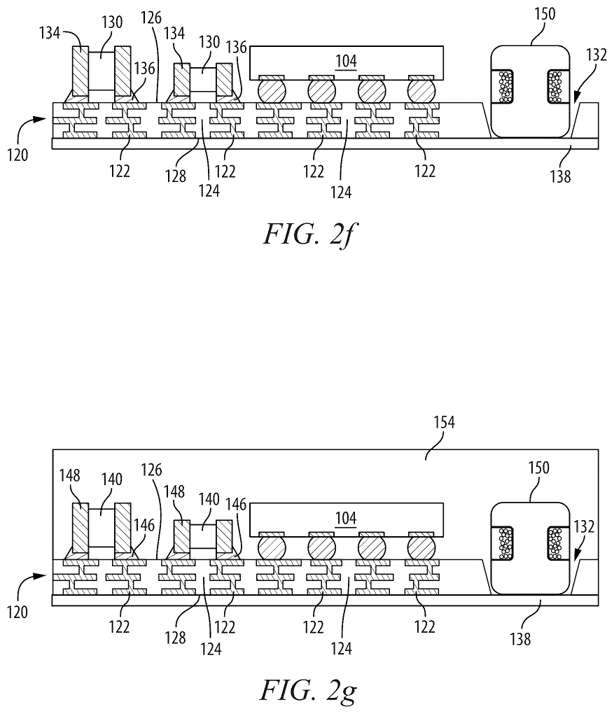

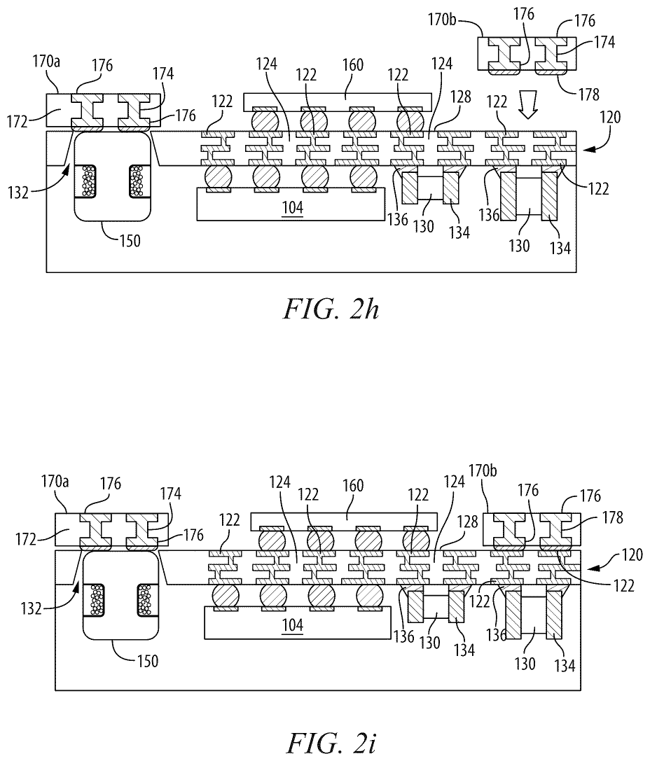

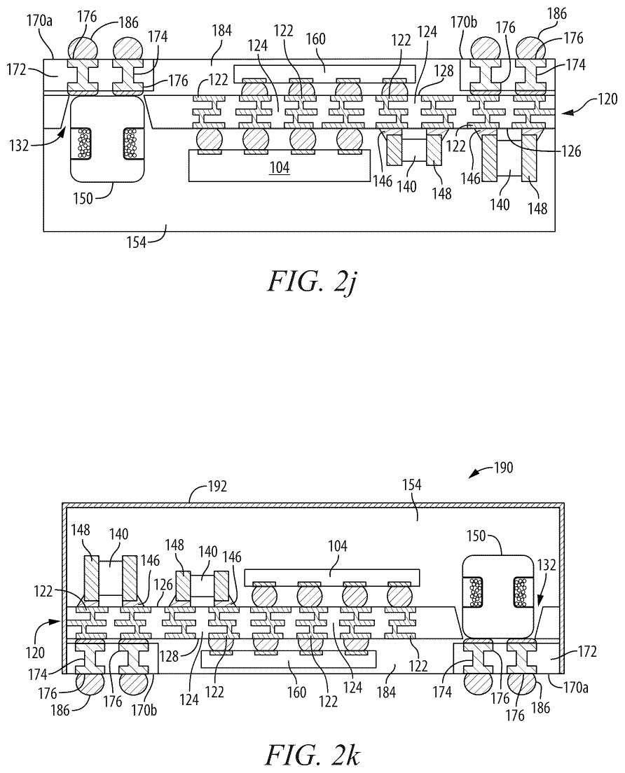

FIGS. 2a-2k illustrate a process of forming a dual-side molded system-in-package (DSmSiP) with tall components. FIG. 2a shows a cross-sectional view of multi-layered interconnect substrate 120 including conductive layers 122 and insulating layers 124. While only a single substrate 120 suitable to form a single semiconductor package is shown, hundreds or thousands of units are commonly manufactured and processed as part of a single substrate 120 before being singulated from each other, using the same steps described herein performed en masse. A separate substrate 120 could also be used for each unit being manufactured, the substrates being singulated before the steps shown herein and a plurality of individual substrates being placed on a common carrier for processing.

Conductive layers 122 can be one or more layers of Al, Cu, Sn, Ni, Au, Ag, or other suitable electrically conductive material. Conductive layers 122 can be formed using PVD, CVD, electrolytic plating, electroless plating, or other suitable metal deposition process. Conductive layers 122 provide horizontal electrical interconnect across substrate 120 and vertical electrical interconnect between top surface 126 and bottom surface 128 of substrate 120. Portions of conductive layers 122 can be electrically common or electrically isolated depending on the design and function of semiconductor die 104 and the DSmSiP being formed.

Insulating layers 124 contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers can be formed using PVD, CVD, printing, lamination, spin coating, spray coating, sintering, thermal oxidation, or other suitable processes. Insulating layers 124 provide isolation between conductive layers 122. Any other suitable type of package substrate or leadframe is used for substrate 120 in other embodiments.

An area 130 of substrate 120 remains reserved for the later formation of an opening 132 in FIG. 2b. The footprint of area 130 typically, but not necessarily, remains free of conductive layers 122 to make the formation of opening 132 more straightforward. Opening 132 is formed by laser ablation with a laser 134. A focused laser beam from laser 134 ablates or vaporizes material of substrate 120 to form opening 132. In other embodiments, opening 132 is formed by mechanical drilling, chemical or plasma etching, punching, or another suitable process. Opening 132 is formed completely through substrate 120, from surface 126 to surface 128.

In FIGS. 2c and 2d, an insulating film 138 is laminated onto bottom surface 128. FIG. 2c is a perspective view of one exemplary layout, while FIG. 2d is another partial cross-section. The layout view of FIG. 2c shows contact pads 122a, where discrete components will later be mounted, and an area 122b where a semiconductor die 104 will be mounted. Area 122b does not illustrate individual flip-chip pads for ease of illustration and is instead illustrated simply as a boundary of the area. In practice, area 122b will have numerous contact pads, significantly smaller than contact pads 122a, suitable for flip-chip mounting semiconductor die 104.

In some embodiments, insulating film 138 comes with a pre-applied pressure-sensitive or heat activate adhesive, or a thin layer of adhesive can be applied to the film or substrate 120 before laminating. A temporary or low-tack adhesive is used to allow the film to be subsequently removed, e.g., a thermal or UV releasable adhesive. Film 138 is at least large enough to cover opening 132, and is typically as large as, or slightly larger than, substrate 120. The material for film 138 can be polyimide, polyester, polyolefin, PVC, a solder mask film, a temporary masking film, or another suitable material. In other embodiments, insulating film 138 can include a conductive material, e.g., copper foil.

In FIG. 2e, semiconductor die 104 along with any other desired electrical components 140 are picked and placed over substrate 120 and then mounted to the substrate. Semiconductor die 104 is one of the semiconductor die from FIG. 1c, or another semiconductor die with different functionality but formed in a similar manner. Electrical components 140 can be discrete active or passive electrical devices, such as a diode, transistor, resistor, capacitor, or inductor. Electrical components 140 can include additional semiconductor die, semiconductor packages, surface mount devices, RF components, discrete active or passive electrical devices, and may include integrated passive devices (IPDs). Components 140 are electrically and physically coupled to substrate 120 by reflowing solder paste 146 between terminals 148 and contact pads of conductive layer 124 while solder bumps 114 are reflowed to attach semiconductor die 104. An underfill is optionally used under any of the mounted components as desired.

Electrical components 140 and semiconductor die 104 are mounted onto top surface 126. In addition, a taller component 150, e.g., an inductor, is picked and placed over opening 132. Taller component 150 is mounted onto insulating film 138 within opening 132 in FIG. 2f. Terminals 148 of taller component 150 are optionally embedded in insulating film 138. In other embodiments, taller component 150 has flat contact pads that lay flat on insulating film 138 with optional solder bumps that may be embedded in insulating film 138.

Taller component 150 mounted in opening 132 is typically an inductor or capacitor, but any electrical component can be disposed in the opening. Typically opening 132 would only be used for components taller than those components mounted directly on surface 126 of substrate 120. Taller in this context means taller than the tallest component mounted onto top surface 126 of substrate 120. In some embodiments, taller component 150 in opening 132 is between 20-50% taller than the tallest component on surface 126.

Being disposed in opening 132 lowers taller component 150 compared to an alternative scenario where the taller component is mounted on surface 126 so that the top surface of the taller component is approximately even with the top surface of the components on surface 126. In some embodiments, taller component 150 remains extending significantly above the components on surface 126, but being disposed in opening 132 still provides the benefit of reducing the overall package size. In other embodiments, taller component 150 is only slightly taller than the components on surface 126 and being placed in opening 132 lowers the top of the taller component, compared to being placed on surface 126, to significantly below the tops of the components that are mounted on surface 126.

In FIG. 2g, an encapsulant or molding compound 154 is deposited over substrate 120, semiconductor die 104, electrical components 140, and taller component 150. Encapsulant 154 extends into opening 132 to fully encapsulate taller component 150. Encapsulant 154 is deposited using a paste printing, compression molding, transfer molding, liquid encapsulant molding, vacuum lamination, spin coating, or other suitable applicator. Encapsulant 154 can be liquid or granular polymer composite material, such as epoxy resin, epoxy acrylate, or another suitable polymer, with or without a filler, e.g., silica.

Encapsulant 154 is non-conductive, provides structural support, and environmentally protects the embedded electrical components from external elements and contaminants. The resulting encapsulated assembly, as shown in FIG. 2g, features encapsulant 154 forming a continuous, protective coating that adheres to substrate 120 and envelops semiconductor die 104, electrical components 140, and taller component 150. This configuration shields the delicate structures from mechanical stress, thermal cycling, and environmental factors such as humidity or dust, thereby enhancing the reliability and longevity of the semiconductor package.

In FIG. 2h, substrate 120 and the encapsulated components are flipped so that bottom surface 128 of substrate 120 is available for processing. Any desired additional electrical components 160 are mounted onto surface 128. Electrical components 160 can include discrete active or passive components, chiplets, semiconductor packages, semiconductor die, or any other type of electrical component. In addition, one or more PCB bars or e-bars 170 are mounted onto substrate 120.

E-bars 170 are formed on a thin dielectric substrate or core 172, such as a glass-reinforced epoxy laminate (e.g., FR-4) or a high-density interconnect (HDI) material. A series of micro-drilled holes are then formed through the dielectric substrate using laser drilling or mechanical drilling techniques, defining the locations of the conductive vias 174. The holes are subsequently plated with a conductive material, typically copper, via an electroplating process, ensuring continuous electrical pathways through core 172.

Contact pads 176 are optionally plated over top and bottom surfaces of core 172 at the same time as vias 174 are plated, or in a separate photolithography and etching process. The resulting e-bar 170 is a compact, rigid structure with a thickness typically ranging from 0.1 mm to 1.0 mm, tailored to the specific packaging requirements. A footprint size of e-bar 170 can include any suitable length and width and does not need to be strictly rectangular in plan view. In some embodiments, e-bars 170 extend for an entire length or width of substrate 120. In one embodiment, four e-bars 170 are used, with one of the e-bars along each of four sides of unit substrate 120, to form a perimeter of e-bars around the substrate. A plurality of e-bars 170 can be disposed with each one of the plurality of e-bars disposed along a different respective edge of substrate 120.

Solder bumps 178 are formed on contact pads 176 on one side of e-bars 170 as described above for the formation of solder bumps 114. E-bars 170 are disposed with solder bumps 178 oriented toward substrate 120. E-bar 170a is mounted onto substrate 120 over taller component 150. While not shown in FIG. 2h, e-bar 170a is mounted directly to substrate 120 in other cross-sections. E-bar 170b is mounted to substrate 120 and may extend over other taller components 150 in other cross-sections. In FIG. 2i, solder bumps 178 are reflowed onto contact pads of conductive layer 122 to physically and electrically couple e-bars 170 to substrate 120. Some solder bumps 178 are also reflowed onto contact pads or terminals 148 of taller component 150.

In FIG. 2j, encapsulant 184 is deposited over e-bars 170 and electrical components 160 using any of the processes and materials described above for encapsulant 154. Encapsulant 184 is deposited coplanar to e-bars 170 using film-assisted molding. Components 160 have a shorter height over substrate 120 than e-bars 170 and are therefore completely covered in encapsulant 184. In other embodiments, components 160 have surfaces exposed from or coplanar to encapsulant 184. In some embodiments, e-bars 170 are covered in encapsulant 184, and then contact pads 176 are exposed by backgrinding or by forming openings through the encapsulant by chemical etching, laser drilling, or another suitable process. Solder bumps 186 are formed on contact pads 176 as described above for bumps 114 on contact pads 112.

In FIG. 2k. the panel of substrate 120, encapsulants 154 and 184, and the encapsulated components, is flipped so that encapsulant 154 is again oriented up or otherwise available for processing. A large panel of multiple DSmSiP modules 190 is typically formed together, and then singulated through substrate 120 and encapsulants 154 and 184 to separate the DSmSiP modules from each other.

To address electromagnetic interference (EMI), radio frequency interference (RFI), harmonic distortion, and other inter-device interference, a shielding layer 192 is optionally formed over DSmSiP module 190. Shielding layer 192 is deposited, printed, sputtered, plated, or otherwise formed. Plating can be performed by CVD, PVD, other sputtering methods, electroplating, electroless plating, or another suitable metal deposition process. Shielding layer 192 includes one or more layers of Al, Cu, Sn, Ni, Au, Ag, stainless steel, or other suitable electrically conductive material.

Singulating through encapsulant 154, substrate 120, and encapsulant 184 to form individual DSmSiP modules 190 prior to forming shielding layer 192 allows the shielding layer to be formed on side surfaces of the DSmSiP module. Shielding layer 192 extending down side surfaces of DSmSiP module 190 helps to protect from laterally incident EMI. Portions of conductive layer 122 are exposed at side surfaces of substrate 120 in some embodiments to physically and electrically connect to shielding layer 192, thereby grounding the shielding layer to improve performance.

FIG. 2k shows a completed DSmSiP module 190 using an efficient packaging structure to implement taller electrical components 150 within a shorter package than in the prior art. Disposing taller components 150 within an opening or trench 132 of substrate 120 reduces the overall package height.

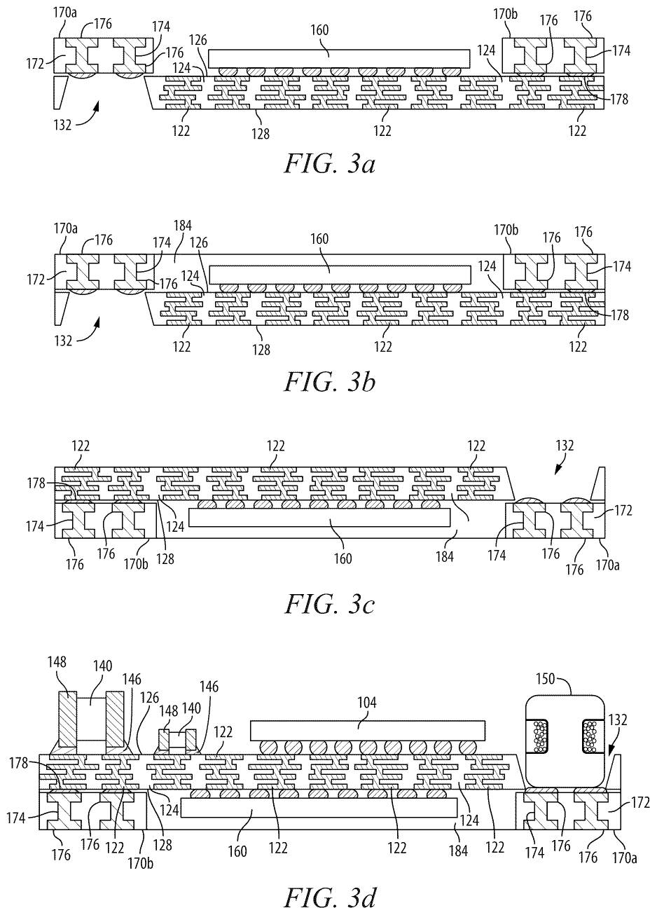

FIGS. 3a-3d illustrate an alternative process flow where bottom surface 128 of substrate 120 is processed before top surface 126. In FIG. 3a, substrate 120 already has opening 132 formed. Opening 132 can be formed from either side of substrate 120. E-bars 170 and electrical components 160 are mounted onto surface 128 as described above. E-bar 170a extends over opening 132. Encapsulant 184 is deposited in FIG. 3b as described above. Solder bumps 186 are optionally formed at this stage.

The panel is flipped in FIG. 3c so that surface 126 is exposed for processing. Electrical components 140, semiconductor die 104, and taller component 150 are mounted in FIG. 3d as described above. However, taller component 150 is mounted directly onto e-bar 170a in opening 132 rather than onto a separate insulating film first as in the previous embodiment. Encapsulant 154 and shielding layer 192 are formed as described above to complete a DSmSiP module.

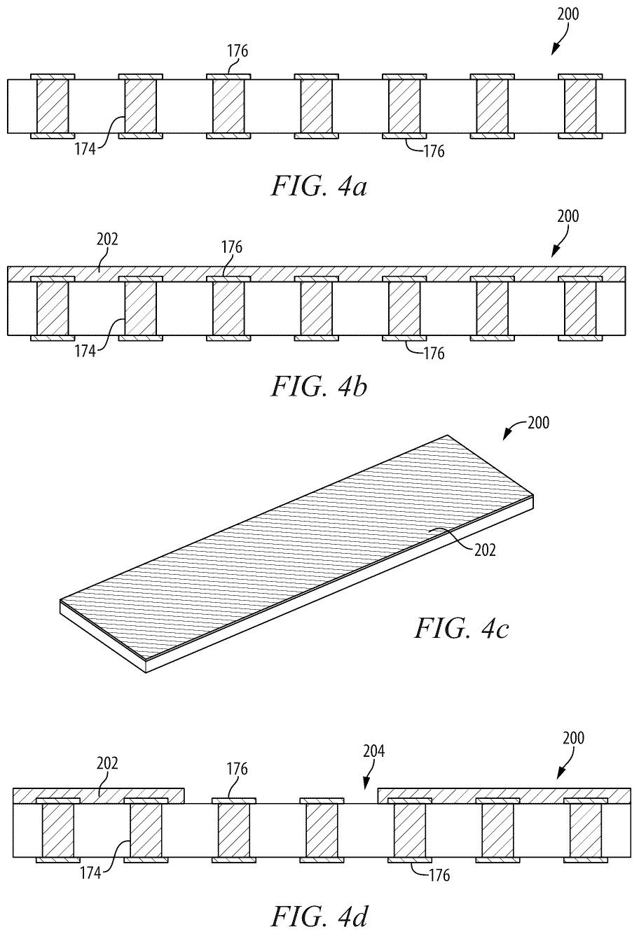

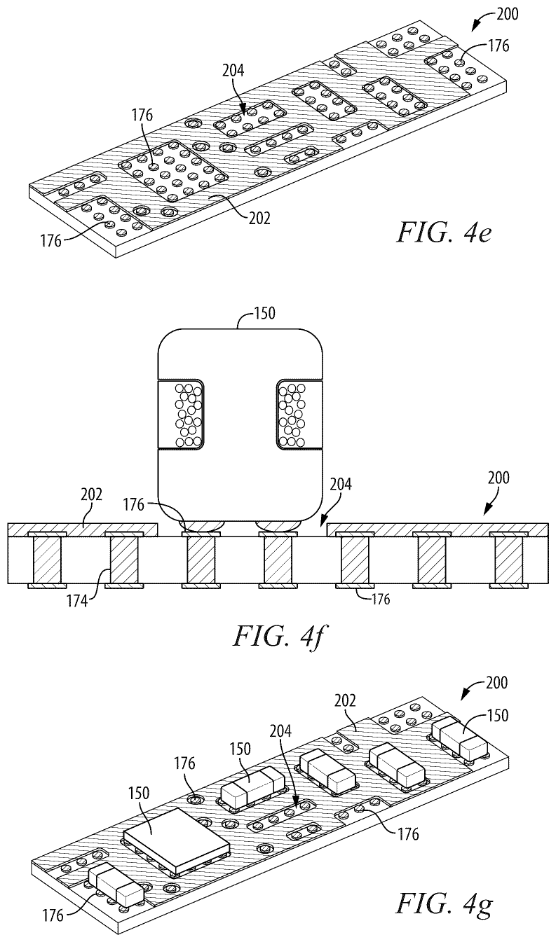

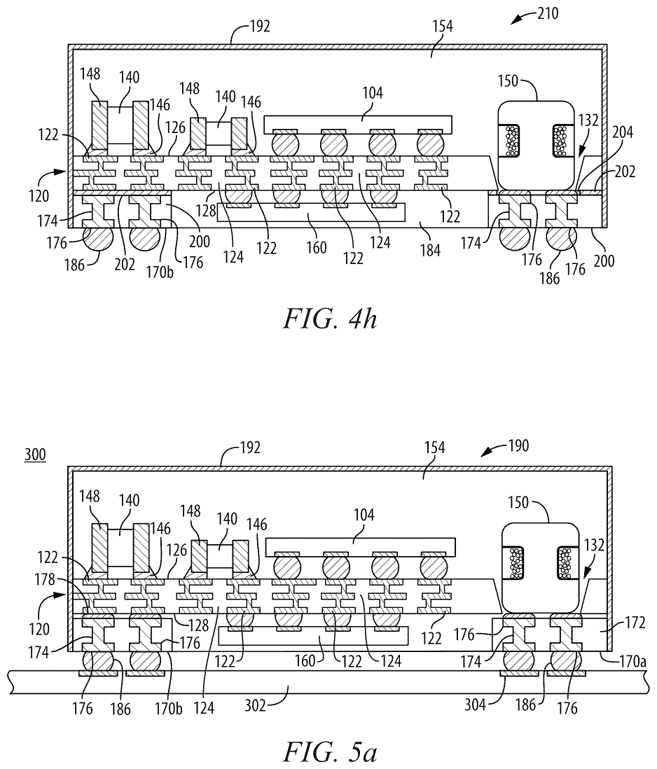

FIGS. 4a-4h illustrate the usage of patterned e-bars 200. FIG. 4a shows a cross-sectional view of e-bar 200. E-bar 200 is formed and structured similarly to e-bar 170 above. E-bar 200 has multiple rows and columns of conductive vias 174 in plan view. Each conductive via 174 has a UBM or contact pad 176 on the top and bottom of the via. In FIGS. 4b and 4c, a conductive layer 202 is formed on one surface of e-bar 200. FIG. 4b is a cross-sectional view and FIG. 4c is a perspective view. Conductive layer 202 is formed of materials and using methods as described above for other conductive layers. Conductive layer 202 completely covers e-bar 200. Each conductive via 174 and contact pad 176 is electrically connected to each other by conductive layer 202.

In FIGS. 4d and 4e, conductive layer 202 is patterned to expose select contact pads 176 in one or more openings 204. Again, FIG. 4d is a cross-section while FIG. 4e shows a perspective view. Conductive layer 202 can be patterned using any suitable means, e.g., chemical etching, photolithography, routing, or laser ablation. In some embodiments, contact pads 176 are formed of, or have a coating of, a different material than conductive layer 202 to allow the conductive layer to be etched without removing the underlying contact pads. Conductive layer 202 is removed at locations where taller components 150 are desired to be mounted, while the conductive layer remains covering e-bar 200 elsewhere as additional EMI shielding. FIGS. 4f and 4g illustrate exemplary taller components 150 mounted onto e-bar 200 in openings 204 of conductive layer 202. Components 150 can be any desired electrical components, e.g., a mix of inductors, capacitors, and semiconductor subpackages.

FIG. 4h shows a DSmSiP module 210 with e-bars 200. E-bars 200 are mounted onto substrate 120 with taller components 150 in openings 132 before encapsulation with encapsulants 154 and 184. In one embodiment, conductive layer 202 is patterned on e-bar 200, but the e-bars are disposed on substrate 120 without taller components 150 already attached. In that embodiment, the process flow of either FIGS. 2a-2k or FIG. 3a-3d can be followed with the addition of conductive layer 202 as a patterned shielding layer. Conductive layer 202 can be electrically connected to shielding layer 192 by e-bar 200 extending to the shielding layer, or through conductive layers 122 of substrate 120.

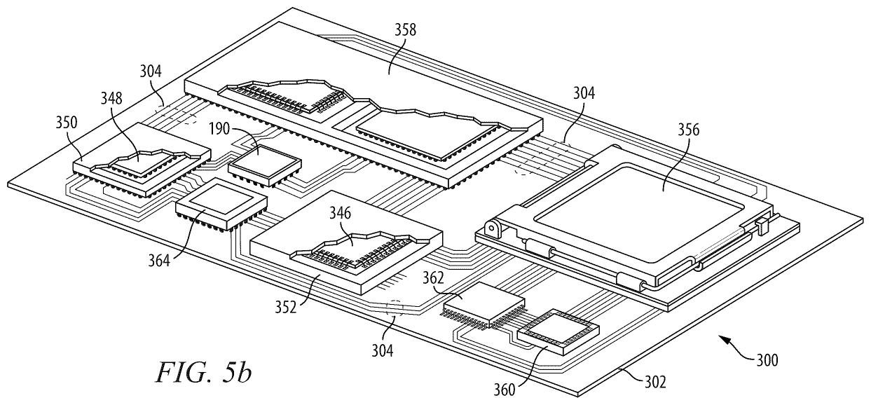

FIGS. 5a and 5b illustrate integrating the above-described semiconductor packages, e.g., DSmSiP module 190, into a larger electronic device 300. FIG. 5a illustrates a partial cross-section of DSmSiP module 190 mounted onto a printed circuit board (PCB) or other substrate 302 as part of electronic device 300. Solder bumps 186 are reflowed onto conductive layer 304 of PCB 302 to physically attach and electrically connect the semiconductor package to the PCB. In other embodiments, thermocompression or another suitable attachment and connection methods are used. In some embodiments, an adhesive or underfill layer is used between DSmSiP module 190 and PCB 302. Semiconductor die 104 and the other components in DSmSiP module 190 are electrically coupled to conductive layer 304 through substrate 120, e-bars 170, and solder bumps 186.

FIG. 5b illustrates electronic device 300 having a chip carrier substrate or PCB 302 with a plurality of semiconductor packages disposed on a surface of PCB 302, including DSmSiP module 190. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 5b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a substrate;
forming an opening through the substrate;
laminating an insulating film onto a first surface of the substrate;
disposing a first electrical component on the insulating film in the opening;
disposing a second electrical component on a second surface of the substrate opposite the first surface;
depositing a first encapsulant over the first electrical component and second electrical component;
removing the insulating film;
disposing a third electrical component over the first surface of the substrate;
disposing an e-bar on the first surface of the substrate; and
depositing a second encapsulant over the third electrical component and e-bar.

2. The method of claim 1, further including:
forming a conductive layer over the e-bar; and
patterning the conductive layer prior to disposing the e-bar on the first surface of the substrate.

3. The method of claim 1, further including forming a shielding layer over the first encapsulant.

4. The method of claim 1, further including depositing the second encapsulant with a surface of the second encapsulant coplanar to a surface of the e-bar.

5. The method of claim 1, further including forming a solder bump on the e-bar opposite the substrate.

6. The method of claim 1, further including disposing a plurality of e-bars with each one of the plurality of e-bars disposed along a respective edge of the substrate.

7. A method of making a semiconductor device, comprising:
providing a substrate;
forming an opening through the substrate;
laminating an insulating film onto a first surface of the substrate;
disposing a first electrical component on the insulating film in the opening;
disposing a second electrical component on a second surface of the substrate opposite the first surface; and
depositing a first encapsulant over the first electrical component and second electrical component.

8. The method of claim 7, further including:
disposing a third electrical component over the first surface of the substrate; and
disposing an e-bar on the first surface of the substrate.

9. The method of claim 8, further including depositing a second encapsulant over the third electrical component and e-bar with a surface of the second encapsulant coplanar to a surface of the e-bar.

10. The method of claim 8, further including:
forming a conductive layer over the e-bar; and
patterning the conductive layer.

11. The method of claim 8, further including forming a solder bump on the e-bar opposite the substrate.

12. The method of claim 8, further including disposing a plurality of e-bars with each one of the plurality of e-bars disposed along a respective edge of the substrate.

13. The method of claim 7, further including forming a shielding layer over the first encapsulant.

14. A method of making a semiconductor device, comprising:
providing a substrate;
forming an opening through the substrate;
disposing a first electrical component in the opening;
disposing a second electrical component over the substrate; and
depositing a first encapsulant over the first electrical component and second electrical component.

15. The method of claim 14, further including disposing a third electrical component over the substrate opposite the second electrical component.

16. The method of claim 14, further including disposing an e-bar over the substrate opposite the second electrical component.

17. The method of claim 16, further including depositing a second encapsulant over the e-bar.

18. The method of claim 16, further including:
forming a conductive layer over the e-bar; and
patterning the conductive layer.

19. The method of claim 14, further including forming a shielding layer over the first encapsulant.

20. A semiconductor device, comprising:
a substrate;
an opening formed through the substrate;
a first electrical component disposed in the opening;
a second electrical component disposed over the substrate; and
a first encapsulant deposited over the first electrical component and second electrical component.

21. The semiconductor device of claim 20, further including a third electrical component disposed over the substrate opposite the second electrical component.

22. The semiconductor device of claim 20, further including an e-bar disposed over the substrate opposite the second electrical component.

23. The semiconductor device of claim 22, further including a second encapsulant deposited over the e-bar.

24. The semiconductor device of claim 22, further including a conductive layer formed over the e-bar and patterned to form an opening.

25. The semiconductor device of claim 20, further including a shielding layer formed over the first encapsulant.
